(19) United States
(12) Patent Application Publication
(10) Pub. No.: US 2021/0292894 A1
(43) Pub. Date: Sep. 23, 2021

(54) TEMPERATURE SENSOR FOR END POINT DETECTION DURING PLASMA ENHANCED CHEMICAL VAPOR DEPOSITION CHAMBER CLEAN

(71) Applicant: Applied Materials, Inc., Santa Clara, CA (US)

(72) Inventors: Fei PENG, San Jose, CA (US); Beom Soo PARK, San Jose, CA (US); Soo Young CHOI, Fremont, CA (US); Sanjay D. YADAV, San Jose, CA (US); Young-Jin CHOI, San Jose, CA (US); Himanshu JOSHI, Fremont, CA (US)

(73) Assignees: Applied Materials, Inc., Santa Clara, CA (US); Applied Materials, Inc., Santa Clara, CA (US)

(21) Appl. No.: 16/326,651

(22) PCT Filed: Aug. 18, 2017
(86) PCT No.: PCT/US2017/047524

§ 371 Date: Feb. 19, 2019

Related U.S. Application Data
(60) Provisional application No. 62/377,266, filed on Aug. 19, 2016.

(51) Int. Cl. C23C 16/44; C23C 16/52; H01J 37/32; G01K 1/02

(52) U.S. Cl. CPC C23C 16/4405; C23C 16/52; H01J 2237/3321; H01J 37/32522; G01K 1/026; H01J 37/32862

(57) ABSTRACT

Embodiments described herein generally relate to a substrate processing chamber, and more specifically to an apparatus and method for monitoring a cleaning processing for the substrate processing chamber. A processor receives one or more temperature readings from one or more sensors disposed in a substrate processing chamber. The processor determines a peak for each temperature reading from the one or more temperature readings, which indicate an end of exothermic film clean reaction. Upon determining that each temperature reading has peaked, the process issues a notification to cease the cleaning process.

### BACKGROUND

### Field

Embodiments described herein generally relate to a substrate processing chamber, and more specifically, to a chamber clean end point detection apparatus and method.

### Description of the Related Art

Flat panel displays (FPD) are commonly used for active matrix displays such as computer and television monitors, personal digital assistants (PDAs), and cell phones, as well as solar cells and the like. Plasma enhanced chemical vapor deposition (PECVD) are employed in flat panel display fabrication to deposit thin film on a substrate in a vacuum processing chamber on a substrate support assembly. PECVD is generally accomplished by energizing mixed process gas into a plasma within the vacuum processing chamber, and depositing a film on the substrate from the energized mixed process gas.

Chamber Clean End Point Detection (EPD) has become an increasingly more prevalent feature for in-situ, self-clean PECVD systems. After film deposition on a substrate, the chamber walls of PECVD chambers have a tendency to accumulate film deposition as well. Film deposition on chamber walls have the tendency to flake, thus resulting in particles falling on the surface of the substrate. To avoid substrate contamination from falling particles, the substrate processing chamber may undergo a cleaning process with a cleaning gas, such as NF₃. Conventional cleaning methods, however, have several downfalls. For example, if the NF₃ clean time prematurely ends, and is shorter than what is required, particle issues remain from residual film on the chamber sidewalls. If on the other hand the NF₃ clean time exceeds the time required to adequately clean the chamber sidewalls, the cost of NF₃ gas consumption will rise. Additionally, the diffuser fluoridation will become accelerated, thus decreasing the lifetime of the diffuser.

Therefore, an improved EPD method is highly desirable for display PECVD chamber.

### SUMMARY

Embodiments described herein generally relate to a substrate processing chamber, and more specifically to an apparatus and method for monitoring a cleaning process for the substrate processing chamber. A processor receives one or more temperature readings from one or more sensors disposed in a substrate processing chamber. The processor determines a peak for each temperature reading from the one or more temperature readings, which indicate an end of exothermic film clean reaction. Upon determining that each temperature reading has peaked, the process issues a notification to cease the cleaning process.

In another embodiment, and end point detection (EPD) system is disclosed herein. The EPD system includes a plurality of sensors and an EPD controller. The plurality of sensors is disposed in a substrate processing chamber. Each sensor is configured to monitor a temperature of a specific area of a component disposed in the substrate processing chamber. The EPD controller is in communication with the plurality of sensor. The EPD controller is configured to monitor a temperature of the substrate processing chamber during a cleaning process. The cleaning process includes comprising an operation. The operation includes receiving a temperature reading from each of the plurality of sensors disposed in the substrate processing chamber, determining a peak for each temperature reading, which indicate an end of exothermic film clean reaction, and responsive to determining that each temperature reading has peaked, issuing a notification to cease the chamber cleaning process.

In another embodiment, a processing chamber is disclosed herein. The processing chamber includes a chamber body, a support plate, a showerhead, and an end point detection (EPD) system. The chamber body defines a processing volume. The support plate is disposed in the processing volume. The support plate is configured to support a substrate during processing. The showerhead is disposed in the processing volume above the support plate. The EPD system includes a plurality of sensors and an EPD controller. Each sensor is configured to monitor one of the showerhead or the support plate processing chamber. The EPD controller is in communication with the plurality of sensors. The EPD controller is configured to monitor a temperature of the processing chamber during a cleaning process.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a cross-sectional view of a processing chamber having an end point detection (EPD) system, according to one embodiment.

FIG. 2 is a flow diagram illustrating a method of monitoring a temperature of a processing chamber during a cleaning process, according to one embodiment.

FIG. 3 is an arrangement illustrating components of the processing chamber of FIG. 1, in more detail.

FIG. 4 is a computing platform for us with the processing chamber of FIG. 1, according to one embodiment.

For clarity, identical reference numerals have been used, where applicable, to designate identical elements that are common between figures. Additionally, elements of one embodiment may be advantageously adapted for utilization in other embodiments described herein.

### DETAILED DESCRIPTION

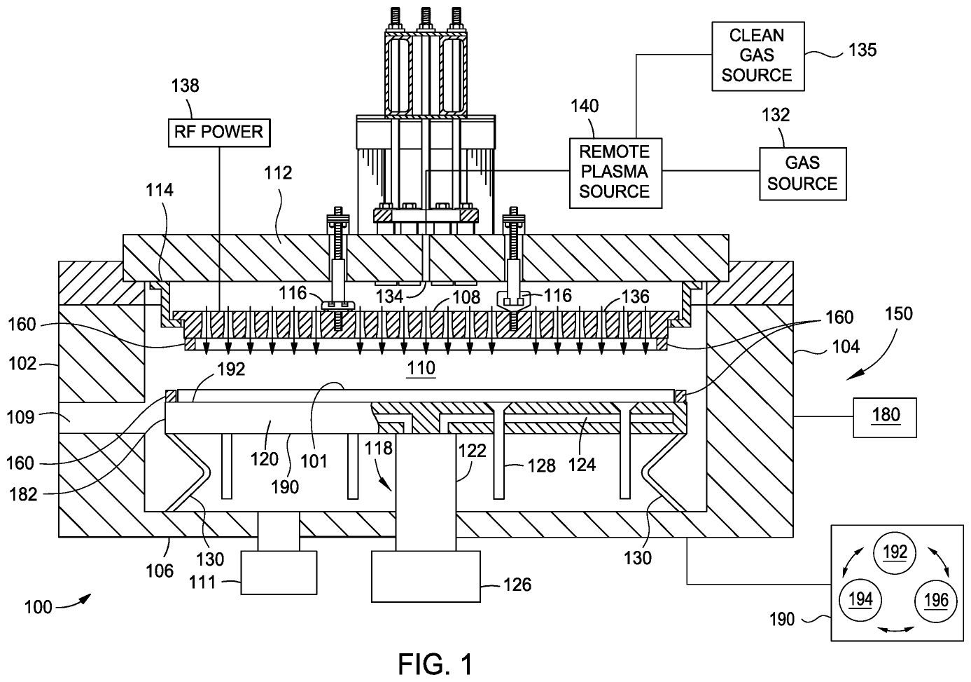

FIG. 1 illustrates a cross-sectional view of a processing chamber 100 having an end point detection (EPD) system 150, according to one embodiment. The EPD system 150 is utilized to control post-deposition cleaning process of the processing chamber 100.

The processing chamber 100 includes a chamber body 102 having sidewalls 104, a bottom 106, and a showerhead 108 that define a processing volume 110. The processing volume 110 is accessed through a slit valve opening 109 formed through the sidewalls 104 to allow entry and egress of a substrate 101 that is processed within the processing volume 110 while disposed on the substrate support assembly 118.

The showerhead 108 is coupled to a backing plate 112. For example, the showerhead 108 may be coupled to the backing plate 112 by a suspension 114 at the periphery of the backing plate 112. One or more coupling supports 116 may be used to couple the showerhead 108 to the backing plate 112 to aid in controlling sag of the showerhead 108.

The substrate support assembly 118 is disposed in the processing volume 110 of the processing chamber 100. The substrate support assembly 118 includes a support plate 120 and a stem 122. The stem 122 is coupled to a bottom surface 191 of the support plate 120. An upper surface 139 of the support plate 120 is configured to support the substrate 101 during processing. The support plate 120 includes temperature control elements 124. The temperature control elements 124 are configured to maintain the substrate support assembly 118 at a desired temperature.

A lift system 126 may be coupled to the stem 122 to raise and lower the support plate 120. Lift pins 128 are moveably disposed through the support plate 120 to space the substrate 101 from the support plate 120 to facilitate robotic transfer of the substrate 101 through the slit valve opening 109.

The substrate support assembly 118 also includes at least one RF return strap 130. The RF return straps 130 are coupled between the support plate 120 and the chamber body 102. For example, one end of the RF return straps 130 may be coupled to the bottom surface 191 of the support plate 120 while the opposite end of the RF return straps 130 may be coupled to the bottom 106 of the chamber body 102. In one embodiment, the RF return straps 130 have a substantially vertical orientation. The RF return straps 130 provide an RF current path from the periphery of the substrate support assembly 118 to the bottom 106 of the chamber body 102.

A gas source 132 may be coupled to the backing plate 112 to provide processing gas through a gas outlet 134 in the backing plate 112. The processing gas flows from the gas outlet 134 through gas passages 136 in the showerhead 108. A vacuum pump 111 may be coupled to control the pressure within the processing volume. A cleaning gas source 135 may also be coupled to the backing plate 112. The cleaning gas source 135 provides a cleaning gas (e.g., NF₃ or other suitable fluorine containing gas) through the gas outlet 134 in the backing plate 112. The cleaning gas flows from the gas outlet 134 through gas passages 135 in the showerhead 108.

An RF power source 138 may be coupled to the backing plate 112 and/or to the showerhead 108 to provide RF power to the showerhead 108. The RF power creates an electric field between the showerhead 108 and the substrate support assembly 118 so that a plasma may be generated from the gases between the showerhead 108 and the substrate support assembly 118.

A remote plasma source 140, such as an inductively coupled remote plasma source, may also be coupled between the gas source 132 and the backing plate 112. Between processing substrates, a cleaning gas from the cleaning gas source 135 may be provided to the remote plasma source 140 so that a remote plasma is generated and provided into the processing volume 110 to clean chamber components. Chamber components may include, but are not limited to, the showerhead 108, backing plate 112, support plate 120, and the like. The cleaning gas may be further excited while in the processing volume 110 by power applied to the showerhead 108 from the RF power source 138. Suitable cleaning gases include but are not limited to NF₃, F₂, and SF₆.

The processing chamber 100 further includes a system controller 190. The system controller 190 includes programmable central processing unit (CPU) 192 that is operable with a memory 194 and a mass storage device, an input control unit, and a display unit (not shown), such as power supplies, clocks, cache, input/output (I/O) circuits, and the liner, coupled to the various components of the processing system to facilitate control of the substrate processing.

To facilitate control of the chamber 100 described above, the CPU 192 may be one of any form of general purpose computer processor that can be used in an industrial setting, such as a programmable logic controller (PLC), for controlling various chambers and sub-processors. The memory 194 is coupled to the CPU 192 and the memory 194 is non-transitory and may be one or more of readily available memory such as random access memory (RAM), read only memory (ROM), floppy disk drive, hard disk, or any other form of digital storage, local or remote. Support circuits 196 are coupled to the CPU 192 for supporting the processor in a conventional manner. Charged species generation, heating, and other processes are generally stored in the memory 194, typically as software routine. The software routine may also be stored and/or executed by a second CPU (not shown) that is remotely located from the processing chamber 100 being controlled by the CPU 192.

The memory 194 is in the form of computer-readable storage media that contains instructions, that when executed by the CPU 192, facilitates the operation of the chamber 100. The instructions in the memory 194 are in the form of a program product such as a program that implements the method of the present disclosure. The program code may conform to any one of a number of different programming languages. In one example, the disclosure may be implemented as a program product stored on a computer-readable storage media for use with a computer system. The program(s) of the program product define functions of the embodiments (including the methods described herein). Illustrative computer-readable storage media include, but are not limited to: (i) non-writable storage media (e.g., read-only memory devices within a computer such as CD-ROM disks readable by a CD-ROM drive, flash memory, ROM chips, or any type of solid-state non-volatile semiconductor memory) on which information is permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure.

The EPD system 150 includes one or more temperature sensors 160 disposed in the processing chamber 100. The one or more temperature sensors 160 are configured to measure a temperature of the processing chamber during the cleaning process. In one example, the one or more temperature sensors are coupled to a bottom surface of the showerhead 108. In this example, at least one temperature sensor is positioned in a corner of the showerhead 108. In another embodiment, the one or more temperature sensors 160 coupled to the support plate 120. In this example, at least one temperature sensor 160 is positioned in a corner of the support plate 120. In yet another example, the one or more temperature sensors 160 may be coupled to a shadow frame positioned about the support plate 120. The one or more temperature sensors 160 may be any suitable sensor capable of measuring the temperature of the substrate. In one example, the one or more temperature sensors 160 are optical temperature sensors.

The EPD system 150 further includes an EPD controller 180. The EPD controller 180 is coupled to the one or more temperature sensors 160. The EPD controller 180 is configured to determine a temperature peak in each of the one or more temperature sensors 160. The temperature peak corresponds to point in which the cleaning process may cease. For example, the peak may indicate an end of exothermic film clean reaction Upon determining that the temperature has peaked in each of the one or more temperature sensors 160, the EPD controller 180 issues a notification to cease the cleaning process. For example, the EPD controller 180 may issue a notification to the system controller 190 to stop the cleaning processing, for example by stopping the follow of NF₃ or other cleaning gas. In another example, the EPD controller 180 issues a notification to a technician, operator, or other person/entity. The notification may be an electronic signal, machine or computer instruction, text message, electronic mail, other electronic communication, telephone message, warning light and/or audible alarm or other suitable communication.

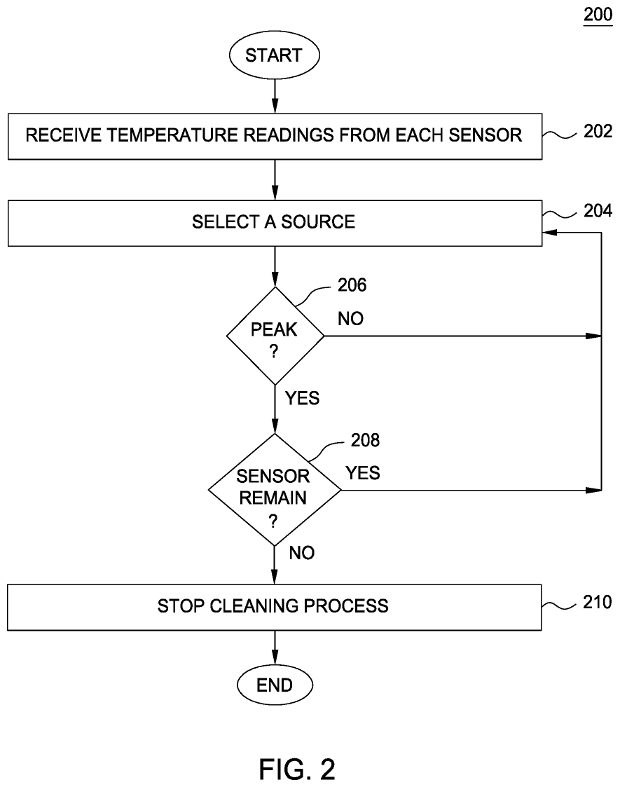

FIG. 2 is a flow diagram illustrating a method 200 of monitoring a temperature of a processing chamber (e.g., processing chamber 100) during a cleaning process, according to one embodiment. The method 200 begins at block 202. At block 202, the EPD controller 180 receives temperature readings from each of the temperature sensors disposed in the processing chamber 100. For example, the EPD controller 180 receives temperature readings from each temperature sensor 160.

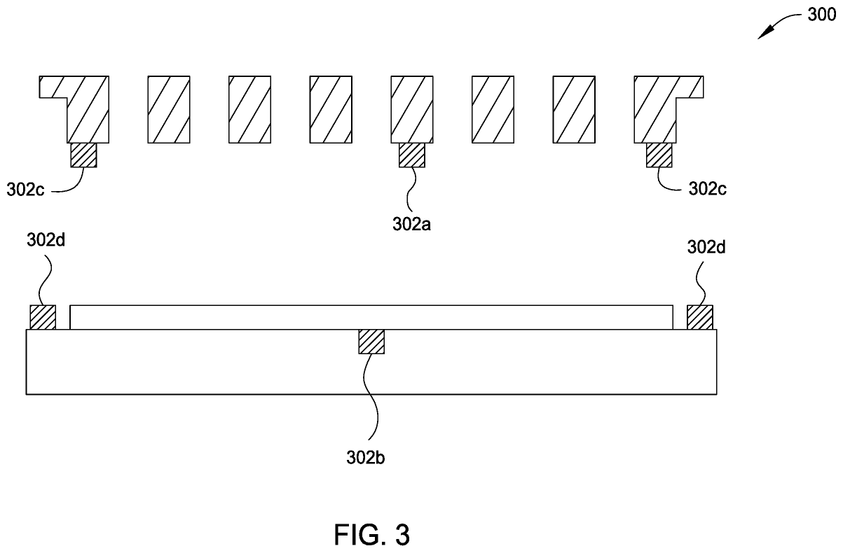

FIG. 3 illustrates a specific example of an arrangement 300 having a plurality of sensors 302a-302d. For example, the FIG. 3 illustrates the showerhead 108 and support plate 120 in an enlarged view. In this example, a first sensor 302a is positioned about a center of the showerhead 108, and periphery sensors 302c are positioned about a periphery of the showerhead 108. Sensor 302a is configured to monitor a temperature of the showerhead 108 near a center of the showerhead 108. Sensors 302c are configured to monitor a temperature of the showerhead 108 near a periphery of the showerhead 108. Using the arrangement 300 in conjunction with the method 200 discussed above in conjunction with FIG. 2, the EPD controller 180 receives temperature readings from each of sensors 302a-302d.

Continuing with method 200, at block 204, the EPD controller 180 selects a first sensor to read. Using the specific example of FIG. 3, the EPD controller 180 may be pre-programmed to first read the measurements monitored by sensor 302a because it was previously determined that the center of the showerhead 108 is cleaned quicker and achieves a higher temperature more quickly than the remaining sensors 302b-302d. Accordingly, the temperature readings for sensor 302a would peak the fastest. In other embodiments, any of sensors 302b-302d may be read first. In additional embodiment, the readings of the sensors 302a-302d may be read simultaneously.

After the EPD controller 180 selects a first sensor to read, EPD controller 180 determines whether the temperature readings have peaked (block 206). For example, EPD controller 180 determines whether the temperature readings for sensor 302a, measuring a temperature of a center of the showerhead 108, has peaked. If the temperature readings have not peaked, then method 200 reverts to block 204, and another sensor is chosen. The peaks indicate an end of exothermic film clean reaction

If, however, the EPD controller 180 determines that the temperature readings for sensor 302a have peaked, then at block 208, the EPD controller 180 determines whether any additional sensors remain. If the EPD controller 180 determines that no additional sensors remain, then at block 210, the EPD controller 180 communicates with the controller 190 to stop the cleaning process. In embodiments in which the EPD controller 180 and the controller 190 are one in the same, the EPD controller 180 stops the cleaning process.

If, however, the EPD controller 180 determines that additional sensors remain, then the method 200 reverts to block 204, and a subsequent sensor is chosen. For example, assume that the temperature readings for sensor 302a peaked around 180° C. Then, EPD controller 180 may subsequently choose sensor 302c for analysis. For example, the EPD controller 180 may be preprogrammed to analyze sensor 302c following sensor 302a analysis. This may be because it was previously determined that the center of the support plate 120 is cleaned quicker and achieves a higher temperature more quickly than the remaining sensors 302b and 302d. This process is continued until all sensors are analyzed.

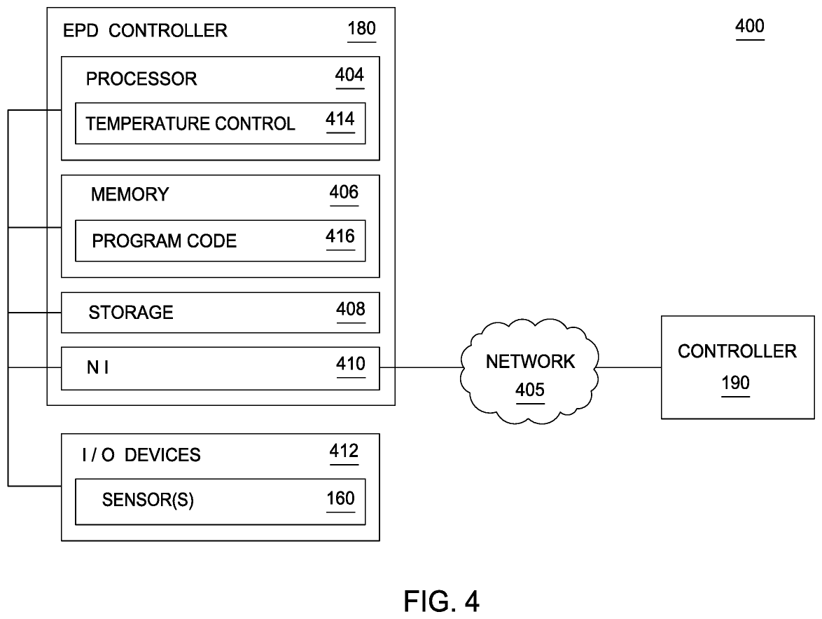

FIG. 4 illustrates computing platform 400, according to one embodiment. Computing platform 400 includes EPD controller 180 and controller 190 communicating via network 405. As shown, EPD controller 180 includes processor 404, memory 406, storage 408, and network interface 410. In some embodiments, the EPD controller 180 may further include one or more I/O devices 412 coupled thereto. The I/O devices 412 includes the sensors 160 disposed in the processing chamber 100.

The processor 404 is included to be representative of a single processor, multiple processors, a single processor having multiple processing cores, and the like. The processor 404 may include a temperature monitoring agent 414. The temperature monitoring agent 414 is configured to retrieve temperature measurements that were monitored by the one or more sensors 160. Additionally, in some embodiments, the temperature monitoring agent 414 is configure to carry out the program code 416 to determine whether any of the temperature readings from any of the sensors 160 have peaked. The peaks indicate an end of exothermic film clean reaction

The memory 406 includes program code 416. The program code 416 is configured to carry out the instructions of monitoring a temperature of a processing chamber during a cleaning process. For example, program code 416 may include the method discussed above in conjunction with FIG. 2.

The storage 408 may be a disk drive storage. Although shown as a single unit, the storage 408 may be a combination of fixed and/or removable storage devices, such as fixed disk drives, removable memory cards, optical storage, network attached storage (NAS), or storage-area-network (SAN). The network interface 410 may be any type of network communications allowing the EPD controller 180 to communicate with other computers via the network 405, such as, for example, controller 190.

While the foregoing is directed to specific embodiments, other and further embodiments may be devised without departing from the basic scope thereof, and the scope thereof is determined by the claims that follow.

What is claimed is:

1. A method of monitoring a substrate cleaning process, comprising:
receiving one or more temperature readings from one or more sensors disposed in a substrate processing chamber;
determining a peak for each temperature reading from the one or more temperature readings, which indicate an end of exothermic film clean reaction; and
responsive to determining that each temperature reading has peaked, issuing a notification to cease the substrate cleaning process.

2. The method of claim 1, wherein receiving one or more temperature readings from one or more sensors disposed in a substrate processing chamber, comprises:
receiving a first plurality of temperature measurements from a first sensor positioned near a center of a showerhead disposed in the substrate processing chamber;
receiving a second plurality of temperature measurements from a second sensor positioned near a center of a substrate support plate disposed in the substrate processing chamber;
receiving a third plurality of temperature measurements from a third sensor positioned near a periphery of the showerhead disposed in the substrate processing chamber; and
receiving a fourth plurality of temperature measurements from a fourth sensor positioned near a periphery of the substrate support plate disposed in the substrate processing chamber.

3. The method of claim 2, wherein determining a peak for each temperature reading from the one or more temperature readings, comprises:
determining that the first plurality of temperature measurements received from the first sensor have peaked.

4. The method of claim 3, further comprising:
determining whether the second plurality of temperature measurements received from the second sensor have peaked.

5. The method of claim 1, wherein responsive to determining that each temperature reading has peaked, issuing a notification to cease the substrate cleaning process, comprises:
communicating with a system controller coupled to the substrate processing chamber to cease the substrate cleaning process.

6. The method of claim 1, wherein the substrate cleaning process is performed using an NF₃ cleaning gas.

7. A temperature monitoring system, comprising:
a plurality of sensors disposed in a substrate processing chamber, each sensor configured to monitor a temperature of a specific area of a component disposed in the substrate processing chamber; and
an end point detection controller in communication with the plurality of sensors, the end point detection controller configured to:
receive a temperature reading from each of the plurality of sensors disposed in the substrate processing chamber;
determine a peak for each temperature reading, which indicate an end of exothermic film clean reaction; and
responsive to determining that each temperature reading has peaked, issue a notification to cease the substrate cleaning process.

8. The temperature monitoring system of claim 7, wherein when receiving one or more temperature readings from one or more sensors disposed in the substrate processing chamber, the end point detection controller is configured to:
receive a first plurality of temperature measurements from a first sensor positioned near a center of a showerhead disposed in the substrate processing chamber;
receive a second plurality of temperature measurements from a second sensor positioned near a center of a substrate support plate disposed in the substrate processing chamber;
receive a third plurality of temperature measurements from a third sensor positioned near a periphery of the showerhead disposed in the substrate processing chamber; and
receive a fourth plurality of temperature measurements from a fourth sensor positioned near a periphery of the substrate support plate disposed in the substrate processing chamber.

9. The temperature monitoring system of claim 8, wherein when determining a peak for each temperature reading from the one or more temperature readings, the end point detection controller is configured to:
determine that the first plurality of temperature measurements received from the first sensor have peaked.

10. The temperature monitoring system of claim 9, wherein the end point detection controller is configured to:
determine whether the second plurality of temperature measurements received from the second sensor have peaked.

11. The temperature monitoring system of claim 7, wherein responsive to determining that each temperature reading has peaked, the end point detection controller is configured to:
communicate with a system controller coupled to the substrate processing chamber to cease the substrate cleaning process.

12. The temperature monitoring system of claim 7, wherein the system controller is configured to:
stop the flow of NF₃ cleaning gas responsive to the communication received from the end point detection controller.

13. A processing chamber, comprising:
a chamber body defining a processing volume;
a support plate disposed in the processing volume, the support plate configured to support a substrate during processing;
a showerhead disposed in the processing volume above the support plate; and
an end point detection system, comprising:
a plurality of sensors configured to monitor one of the showerhead or the support plate disposed in the chamber processing volume; and
an end point detection controller in communication with the plurality of sensors, the end point detection controller configured to monitor a temperature of the showerhead or the support plate during a cleaning process.

14. The processing chamber of claim 13, wherein the end point detection controller is configured to:
receive a temperature reading from each of the plurality of sensors disposed in the substrate processing chamber;
determine a peak for each temperature reading, which indicate an end of exothermic film clean reaction; and
responsive to determining that each temperature reading has peaked, issue a notification to cease the substrate cleaning process.

15. The processing chamber of claim 13, wherein the plurality of sensors comprises:
a first sensor positioned near a center of the showerhead;
a second sensor positioned near a center of the support plate;
a third sensor positioned near a periphery of the showerhead; and
a fourth sensor positioned near a periphery of the support plate.
